(19) United States
(12) Patent Application Publication
(10) Pub. No.: US 2004/0211461 A1
(43) Pub. Date: Oct. 28, 2004

(54) Dye-sensitized solar cell

(76) Inventors: Shinji Murai, Sagamihara-shi (JP); Satoshi Mikoshiba, Yamato-shi (JP); Hiroyasu Sumino, Tokyo (JP); Shuzi Hayase, Kitakyushu-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/761,381

(22) Filed: Jan. 22, 2004

(30) Foreign Application Priority Data
Jan. 23, 2003 (JP) 2003-014332

(51) Int. Cl. H01L 31/00

(52) U.S. Cl. 136/263; 136/256

(57) ABSTRACT

The embodiment of the invention provides a dye-sensitized solar cell comprising a semiconductor electrode containing a dye and carboxylic compound, the dye and carboxylic compound being carried on a surface of the semiconductor electrode, a counter electrode, and an electrolyte composition provided between the semiconductor electrode and the counter electrode, and containing an electrolyte that contains iodine and molten salt of iodide.

### CROSS-REFERENCE TO RELATED APPLICATIONS

This application is based upon and claims the benefit of priority from the prior Japanese Patent Application No. 2003-14332, filed Jan. 23, 2003, the entire contents of which are incorporated herein by reference.

### BACKGROUND OF THE INVENTION

1. Field of the Invention

The present invention relates to a dye-sensitized solar cell.

2. Description of the Related Art

A general, a dye-sensitized solar cell comprises an electrode carrying a dye on the surface of a semiconductor layer that consists essentially of fine particles of metal oxide, that is, an oxide electrode, a transparent electrode opposite to the electrode, and a liquid carrier movement layer interposed between the two electrodes (for example, Jpn. Pat. Appln. KOKAI Publication No. 1-220380). In such a solar cell, the carrier movement layer is liquid, and therefore the cell is called a wet type dye-sensitized solar cell.

This dye-sensitized solar cell operates in the following process. Incident light from the transparent electrode side reaches the dye carried on the semiconductor layer surface, and excites the dye. The excited dye promptly transfers electrons to the semiconductor layer. On the other hand, the dye losing its electrons is positively charged, and receives electrons from ions which have been diffused from the carrier movement layer, and is electrically neutralized. The ions, giving up electrons, are diffused in the transparent electrode, and receive electrons. The oxide electrode and opposite transparent electrode are utilized as a negative electrode and a positive electrode, respectively, and thereby the dye-sensitized solar cell operates as a battery.

In the wet type dye-sensitized solar cell, a low molecular weight solvent is used, and careful shielding is needed to prevent leakage of this solvent. It is, however, difficult to shield perfectly for a long period of time, and the solvent is lost due to evaporation or leakage, which may lead to deterioration of the cell characteristics and adverse effects on the environment. Accordingly, instead of the liquid carrier movement layer, it has been proposed to use a carrier movement layer formed of a liquid electrolyte that contains a molten salt such as imidazolium salt (for example, Jpn. Pat. Appln. KOKAI Publication No. 2002-289268). By using such a solar cell, since there is no problem of evaporation of an organic solvent, the long-term stability is high.

In the above-described dye-sensitized solar cell, however, another problem is known, that is, electrons or holes once injected into the semiconductor layer leak out into the carrier movement layer, for example, into the electrolyte. As a result, the open-circuit voltage is lowered, the short-circuit current of the solar cell is decreased and the overall characteristic of the solar cell declines.

On the other hand, to obtain a dye-sensitized solar cell excellent in optical characteristics such as open-circuit voltage and photoelectric conversion efficiency, it is known to carry a silane compound or the like on a semiconductor layer as a charge transfer control molecule (for example, Jpn. Pat. Appln. KOKAI Publication No. 2001-102103). In this method, the area which is not coated sufficiently with the dye, of the surface of the semiconductor layer, is covered with the charge transfer control molecule, and therefore charge transfer from the surface of the semiconductor layer into the carrier movement layer can be prevented.

In the above-described dye-sensitized solar cell having a charge transfer control molecule, however, since the solvent having the electrolyte dissolved therein is used in the liquid carrier movement layer, the evaporation of an organic solvent occurs as mentioned above, and the long-term stability is not obtained.

As described herein, in the dye-sensitized solar cell using a carrier movement layer containing a molten salt including an imidazolium salt, the open-circuit voltage is lowered, the short-circuit current is decreased and the characteristic of the solar cell declines.

On the other hand, in the dye-sensitized solar cell having a charge transfer control molecule carried on a semiconductor layer thereof, the long-term stability is not obtained owing to problems such as evaporation of an organic solvent.

### BRIEF SUMMARY OF THE INVENTION

It is hence an object of the invention to provide a dye-sensitized solar cell excellent in both photo-electric conversion efficiency and durability.

According to an aspect of the invention, there is provided a dye-sensitized solar cell comprising:

a semiconductor electrode containing a dye and carboxylic compound, the dye and carboxylic compound being carried on a surface of the semiconductor electrode;

a counter electrode; and

an electrolyte composition provided between the semiconductor electrode and the counter electrode, and containing an electrolyte that contains iodine and molten salt of iodide.

### BRIEF DESCRIPTION OF THE SEVERAL VIEWS OF THE DRAWING

FIGS. 1A, 1B, 1C, and 1D are a sectional view showing an example of a process of manufacturing a dye-sensitized solar cell according to the invention.

FIG. 2 is a sectional view showing an example of the dye-sensitized solar cell according to the invention.

### DETAILED DESCRIPTION OF THE INVENTION

The embodiment of the invention will be specifically described below.

A dye-sensitized solar cell of the embodiment of the invention comprises a semiconductor electrode having a dye and carboxylic compound, the dye and carboxylic compound being carried on a surface of the semiconductor electrode; and an electrolyte composition containing a molten salt. Such a dye-sensitized solar cell brings about the following effects.

That is, in a wet type dye-sensitized solar cell, since the characteristic deteriorates due to leakage of solvent, etc., it is preferred to use a molten salt in the electrolyte composition in order to obtain stability for a long term.

However, since electrons or holes injected into the semiconductor layer may leak out, for example, into the electrolyte, the photoelectric conversion efficiency may be lowered, and this problem is particularly noticed when a molten salt is used in the electrolyte composition. This is because, in the electrolyte containing a molten salt, the iodine concentration must be kept high in order to compensate for drop of diffusion velocity of ions due to increase of viscosity, and consequently, a reaction in which substances oxidized in the electrolyte composition are reduced by electrons in the semiconductor layer is promoted.

As a result of investigation by the present inventors, it has been discovered that a dye-sensitized solar cell comprising an electrolyte composition that contains a molten salt and further carrying carboxylic compound on a semiconductor layer having a dye carried thereon can improve not only the durability but also the photoelectric conversion characteristic such as open-circuit voltage and short-circuit current.

That is, the semiconductor electrode has a dye carried on the surface of a semiconductor layer by adsorption or the like. In this semiconductor layer, the dye is not sufficient in adsorbability on the surface of the semiconductor layer and therefore cannot cover the semiconductor layer sufficiently, so that the adsorbed dye is also likely to be peeled off. Therefore, it is considered that, since charge is transferred into the electrolyte composition from the surface of the semiconductor layer which is not sufficiently covered with the dye, when used as the dye-sensitized solar cell, electrons or holes once injected into the semiconductor layer leak out into the electrolyte composition, and the open-circuit voltage is lowered and the short-circuit current is decreased, thereby deteriorating the photoelectric conversion characteristics.

In the embodiment of the invention, by contrast, after carrying a dye on the surface of the semiconductor layer, carboxylic compound is carried on the surface. Therefore, since the surface of the semiconductor layer which is not sufficiently covered with the dye is covered with the carboxylic compound, transfer of charge from the surface of the semiconductor layer into the electrolyte composition can be prevented, so that the semiconductor electrode excellent in optical characteristic such as open-circuit voltage and photoelectric conversion efficiency can be obtained. Further, since the carboxylic compound such as acetic acid, butyric acid or propionic acid is stable even if the electrolyte contains water, and is also high in adsorbability with a semiconductor, a solar cell excellent in photoelectric conversion efficiency and durability is obtained even if the electrolyte contains water.

When the molten salt was used in the electrolyte composition, even if another substance such as silane compound was carried on the semiconductor layer, almost no improvement was noted in the photoelectric conversion efficiency. Causes are estimated in (i) below.

(i) Since the silane compound is inferior in reactivity with an OH group existing on the semiconductor surface such as titanium oxide. Therefore, the silane compound is insufficient in function of protecting the semiconductor layer surface, and electrons or holes injected into the semiconductor layer are likely to leak into the electrolyte composition.

The electrolyte composition and semiconductor electrode used in the dye-sensitized solar cell of the embodiment of the invention will be specifically described below.

### (1) Electrolyte Composition

The electrolyte composition of the embodiment of the invention contains an electrolyte containing iodine molecule (I₂) and molten salt of iodide.

The electrolyte composition may also contain a gelling agent aside from the iodine molecule and molten salt. By gelling the electrolyte composition by the gelling agent, it is effective to entrap iodine having sublimation within the gel, or prevent leakage of the electrolyte composition from the cell.

Further, in addition to iodine molecule and molten salt, the electrolyte composition may also contain inorganic salt of iodide. The electrolyte containing a molten salt is high in viscosity, thereby the diffusion rate of ions may be lowered. By dissolving inorganic salt of iodide in the molten salt, the carrier concentration of the electrolyte can be enhanced.

Moreover, in addition to the iodine molecule and molten salt, the electrolyte composition may also contain a viscosity-lowering agent containing at least one compound selected from the group consisting of iodide of nitrogen-containing heterocyclic compound and salt of aliphatic compound. Such a viscosity-lowering agent has a function of lowering the viscosity of the electrolyte composition. And since the viscosity-lowering agent is a molten salt not containing an iodine (I) component, it is not evaporated, unlike an organic solvent.

(Electrolyte)

The electrolyte used in the embodiment of the invention contains an iodine (I) element. In particular, it is preferred to contain a reversible oxidation-reduction pair consisting of I⁻ and I₃⁻. The reversible oxidation-reduction pair can be supplied, for example, from a mixture of iodine molecule (I₂) and molten salt of iodide.

Such an oxidation-reduction pair is preferred to show a smaller oxidation-reduction potential than an oxidation potential of a dye described later by about 0.1 to 0.6 V. In the oxidation-reduction pair showing a smaller oxidation-reduction potential than the oxidation potential of the dye by about 0.1 to 0.6 V, for example, a reducing seed such as I⁻ can receive a positive hole from the oxidized dye. As such an oxidation-reduction pair is contained in the electrolyte, the speed of charge transfer between the semiconductor electrode and a conductive layer can be increased, and the open-circuit voltage can be heightened.

The iodine concentration of the electrolyte composition is preferred to be controlled in a range of 0.05 mol/L to 5 mol/L from the viewpoint of obtaining a high ion diffusion velocity. A more preferred range is 0.1 mol/L to 3 mol/L.

The usable molten salt of iodide includes an iodide of a nitrogen-containing heterocyclic compound such as an imidazolium salt, a pyridinium salt, a quaternary ammonium salt, a pyrolidinium salt, a pyrazolidium salt, an isothiozolidinium salt, and an isooxazolidium salt.

Examples of the molten salt of iodide include 1-methyl-3-propyl imidazolium iodide, 1,3-dimethyl imidazolium iodide, 1-metnyl-3-ethyl imidazolium iodide, 1-methyl-3-pentyl imidazolium iodide, 1-methyl-3-isopentyl imidazolium iodide, 1-methyl-3-hexyl imidazolium iodide, 1,2-dimethyl-3-propyl imidazolium iodide, 1-ethyl-3-isopropyl imidazolium iodide, 1-propyl-3-propyl imidazolium iodide, pyrolidinium iodide, ethylpyridinium iodide, butyl pyridinium iodide, hexyl pyridinium iodide, and trihexyl methyl ammonium iodide. Among these molten salts of iodide, one type may be used alone or two or more types may be used in combination. Above all, 1-methyl-3-propyl imidazolium iodide is preferred owing to its low viscosity.

Since many of these molten salts are deliquescent, it is allowed to contain water in the molten salt. From the viewpoint of suppressing viscosity elevation of the electrolyte composition due to the molten salt, water may be preliminarily added to the electrolyte. The content of water in the electrolyte is preferred to be about 10 wt. % or less. To suppress viscosity elevation of the electrolyte, it is desired to contain water at least by 0.01 wt. % or more in the electrolyte. A more preferred range is 2 wt. % or less.

(Gelling agent)

To prepare a gel electrolyte layer, a gelling agent may be added to the electrolyte mentioned above. The gelling agent contains a halogen-containing compound, or a metal compound having a valency of two or more, or both of the halogen-containing compound and metal compound. And the gelling agent further contains a compound (hereinafter referred to as compound A) including at least one element selected from the group consisting of N, P and S.

The compound A includes a first compound A and a second compound A. The first compound A includes at least one element selected from the group consisting of N, P and S, and can form an onium salt together with the halogen-containing compound. On the other hand, the second compound A includes at least one element selected from the group consisting of N, P and S, and can form a complex together with the metal compound.

The compound A is preferred to have two or more groups containing at least one atom selected from the group consisting of N, P and S (hereinafter referred to as N—P—S containing groups) per molecule. The N—P—S containing groups existing in one molecule may be of the same type, or two or more different types of N—P—S containing groups may be contained in one molecule. If only one N—P—S containing group is present in one molecule, the degree of polymerization of a polymer of onium salt formed from the first compound A and halogen-containing compound, or the complex formed from the second compound A and metal compound is lowered, and thereby gelling of electrolyte may be difficult. The number of N—P—S containing groups per molecule preferably ranges from 2 or more to 1,000,000 or less.

The compound A can belong to, for example, monomer, oligomer, or polymer.

An example of the compound A has a substituent containing at least one atom selected from the group consisting of N, P and S (hereinafter referred to as N—P—S containing substituent) as a main chain or side chain. The position of the N—P—S containing substituent is not particularly specified as far as a desired polymer can be obtained.

The skeleton of the main chain of the compound A is not particularly limited, and may include, for example, polyethylene, polyester, polycarbonate, methyl polymethacrylate, polyacrylonitrile, polyamide, and polyethylene terephthalate.

The usable N—P—S containing substituent includes at least one group selected from the group consisting of a primary amino group, a secondary amino group, a tertiary amino group, a phosphine group (PH₂—), and a group delivered from a nitrogen-containing heterocyclic compound. The compound A may have the same kind of N—P—S containing substituent in one molecule, but may also have two or more different kinds of N—P—S containing substituents in one molecule. In particular, a primary amino group, a secondary amino group, and a tertiary amino group are preferred.

A tertiary nitrogen including a primary amino group, a secondary amino group, and a tertiary amino group includes, for example, amino group, N-methyl amino group, N,N-dimethyl amino group, N-ethyl amino group, N,N-diethyl amino group, N-propyl amino group, N,N-dipropyl amino group, N-butyl amino group, and N,N-dibutyl amino group.

A nitrogen-containing heterocyclic substituent includes, for example, pyroyl group, imidazoyl group, pyrazoyl group, isothiazoyl group, isooxazoyl group, pyridyl group, pyradinyl group, pyrimidinyl group, pyridadinyl group, indolidinyl group, isoindoyl group, indoyl group, isoazoyl group, purinyl group, quinolidinyl group, isoquinoyl group, quinoyl group, phthaladinyl group, naphthylidinyl group, quinoxaquinidyl group, quinoxazolinyl group, sinoynyl group, phellidinyl group, carbasole group, carbolinyl group, phenanthylidinyl group, actylinyl group, perimidyl group, phenanthroinyl group, phenadinyl group, phenothiadinyl group, phylazanyl group, phenoxadinyl group, pyrrolidinyl group, pyrrolinyl group, imidazolidinyl group, imidazolinyl group, pyralizolidinyl group, pyrazolinyl group, piperidyl group, piperadinyl group, indolinyl group, isoindolinyl group, quinuclidinyl group, morphorinyl group, 1-methyl imidazoyl group, 1-ethyl imidazoyl group, and 1-propyl imidazoyl group. The substituent may also include a spiro ring obtained from at least one type of nitrogen-containing heterocyclic substituent selected from the above, or an assembly of two or more types of nitrogen-containing heterocyclic substituents selected from the above (hetero ring assembly).

Of the compound A, a compound containing N includes, for example, polyvinyl imidazole, poly(4-vinylpyridine), poly(3-vinylpyridine), poly(2-vinylpyridine), polybenzimidazole, bipyridyl, terpyridyl, polyvinyl pyrrole, 1,3,5-tris(3-dimethylamino)propylhexahydro-1,3,5-triazine, tris-2 amino ethylamine, polydiallyl methylamine, polyallyl dimethylamine, polydimethyl allylamine, polyallylamine, polydimethyl aminoethyl methyl methacrylate, and polydimethyl aminoethyl methacrylate. These compounds may be used either alone or in combination of two or more types. Above all, polyvinyl imidazole, poly(4-vinylpyridine), poly(3-vinylpyridine), poly(2-vihylpyridine), and polybenzimidazole are particularly preferred because the electrolyte can be gelled by a small amount. In addition, compounds shown in the following formulas (1) to (5) may be used.

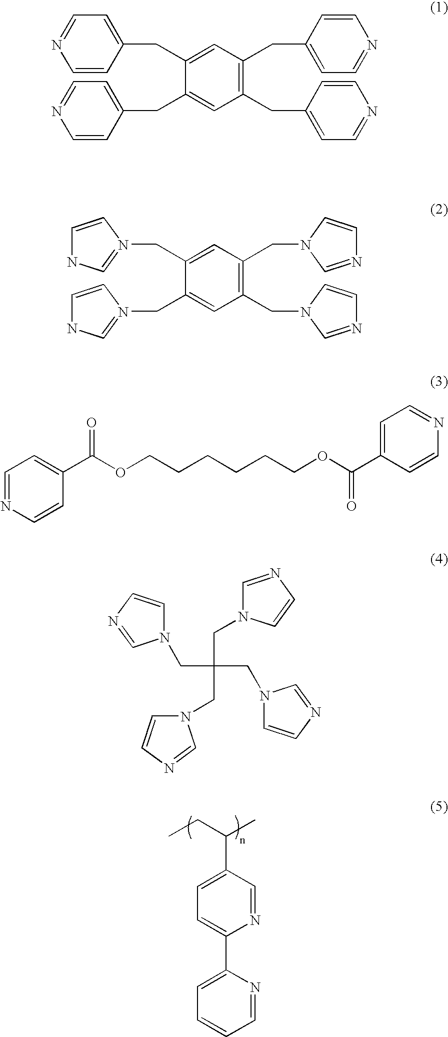

Of the compound A, a compound containing P includes, for example, monomer, oligomer or polymer containing a phosphine group. Specific examples are polyvinylphenyl diphenylphosphine, 1,2-phenylene bisphosphine, 1,3-bis(diphenylphosphino)propane, and 1,5-bis(diphenylphosphino)pentane. These compounds may be used either alone or in combination of two or more types.

Of the compound A, a compound containing S includes, for example, any compound having a thioether structure. Specific examples are bis(methylthio)methane, 1,1-bis(methylthio)-2-nitroethylene, (di-)ethylsulfide, polyvinylphenyl phenylthioether, and ethyl(bisethylthio)acetate. These compounds may be used either alone or in combination of two or more types.

A halogen-containing compound forming a polymer of onium salt together with the compound A is preferably organic halide. The organic halide is likely to form an onium salt, and in particular a multifunctional compound is preferred because the crosslinking density can be enhanced.

The halogen-containing compound is preferred to have two or more halogen atoms per molecule. In such a compound, having different halogen atoms in one molecule, the total number of halogen atoms may be 2 or more, or two or more halogen atoms of one same type may be present in one molecule. If only one halogen atom is contained in one molecule, the degree of polymerization is low in a polymer obtained from the compound A and halogen-containing compound, and it may be hard to gel the electrolyte composition. The number of halogen atoms per molecule is preferably in a range of from 2 or more to 1,000,000 or less.

Examples of the halogen-containing compound having two or more halogen atoms per molecule include dibromomethane, dibromoethane, dibromopropane, dibromobutane, dibromopentane, dibromohexane, dibromoheptane, dibromooctane, dibromononane, dibromodecane, dibromoundecane, dibromododecane, dibromotridecane, dichloromethane, dichloroethane, dichloropropane, dichlorobutane, dichloropentane, dichlorohexane, dichloroheptane, dichlorooctane, dichlorononane, dichlorodecane, dichloroundecane, dichlorododecane, dichlorotridecane, diiodomethane, diiodoethane, diiodopropane, diiodobutane, diiodopentane, diiodohexane, diiodoheptane, diiodooctane, diiodononane, diiododecane, diiodoundecane, diiodododecane, diiodotridecane, 1,2,4,5-tetraxis bromomethyl benzene, epichlorohydrine oligomer, epibromohydrine oligomer, hexabromocylododecane, tris(3,3-dibromo-2-bromopropyl)isocyanuric acid, 1,2,3-tribromopropane, diiodoperfluoroethane, diiodoperfluoropropane, diiodoperfluorohexane, polyepichlorohydrine, copolymer of polyepichlorohydrine and polyethylene ether, and multifunctional halogen compound such as polyepibromohydrine or polyvinyl chloride. As the halogen-containing compound, one or two or more types of organic halides may be used. In particular, an organic halide having two halogen atoms in one molecule is preferred.

A metal compound forming a complex together with the compound A can form a crosslinking structure by metal ions between the metal compounds when the valence of metal is 2 or more, and therefore the electrolyte composition can be gelled by a metal salt having the crosslinking structure. Since the gelling agent including this metal compound is stable even if the solar cell is used for a long period and the temperature of the solar cell is raised to about 50 to 70° C. due to irradiation of sunlight, it is effective to avoid occurrence of phase transfer in the gel electrolyte. As a result, liquid leakage at the time of temperature rise can be prevented, and a high energy conversion efficiency can be maintained even during temperature rise.

A metal compound of valence of 2 or more includes, for example, halide of Mg, halide of Ca, halide of Ba, and halide of transition metal. Metal compounds may be used alone or in combination of two or more types. Specific examples are ZnI₂, MgI₂, MgCl₂, CaI₂, CuI₂, ZnI₂, RuI₃, PtI₄, MnI₂, OsCl₃, IrBr₃, RhI₃, PdI₂, and FeI₂. In particular, a metal iodide is preferably used. It is also possible to use a metal compound having a ligand such as, other than halogen atoms, an organic acid group including an acetic group or an oxalic group, or an inorganic acid group including a carbonic group or a nitric group.

A method of gelling an electrolyte composition precursor will be explained below.

An electrolyte composition precursor A is prepared by dissolving at least one of a halogen-containing compound and a metal compound of valence of 2 or more in an electrolyte, an electrolyte composition precursor B is prepared by dissolving the compound A in an electrolyte, and a material kit containing the obtained electrolyte composition precursor A and electrolyte composition precursor B is stored. The stored electrolyte composition precursor A and electrolyte composition precursor B are mixed when necessary, and the obtained mixed electrolyte composition precursor can be used as a gel electrolyte.

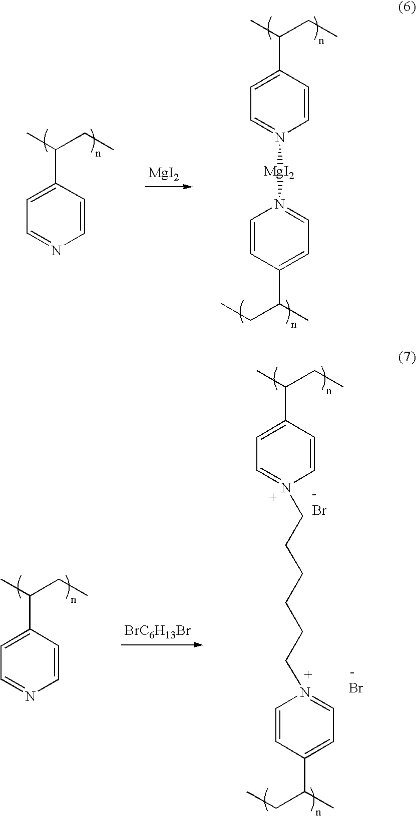

Formula (6) in the above (chem. 2) shows a reaction of polyvinyl pyridine and MgI₂. Formula (7) in (chem. 2) shows a reaction of polyvinyl pyridine and halide. By these reactions, the polymers are crosslinked by metal ions or halogenated alkyl compound, and a gel is formed.

(Inorganic salt of iodide)

In the embodiment of the invention, the electrolyte composition may contain inorganic salt of iodide in addition to the electrolyte described above. Even if the carrier concentration is raised by adding inorganic salt of iodide, there is a possibility of leak of the carrier injected into the semiconductor layer into the electrolyte composition. However, since carboxylic compound is also carried in the semiconductor layer in the embodiment of the invention, the high carrier concentration in the case where the inorganic salt of iodide is added can be effectively utilized.

The inorganic salt of iodide includes iodide of alkaline metal, iodide of alkaline earth metal, and iodide of transition metal. Specific examples are lithium iodide, sodium iodide, cesium iodide, magnesium iodide, calcium iodide, ZnI₂, CuI₂, ZnI₂, RuI₃, PtI₄, MnI₂, RhI₃, PdI₂, and FeI₂. Further, by dissolving at least one type of metal salt of iodide in the electrolyte, an electrolyte composition precursor C is prepared, and it can be contained in the gel electrolyte.

(Viscosity lowering agent)

In the embodiment of the invention, the electrolyte composition may also contain a viscosity-lowering agent in addition to the electrolyte described above. Since a viscosity-lowering agent does not contain an iodine (I) element, the carrier cannot be increased, but by lowering the viscosity of the electrolyte composition, the ion diffusion velocity can be increased, and the photoelectric conversion characteristic can be heightened.

Examples of the viscosity-lowering agent include salts of nitrogen-containing heterocyclic compounds (except halides of nitrogen-containing heterocyclic compound) such as an imidazolium salt, a pyridinium salt, a pyrrolidinium salt, a pyraolidium salt, an isothiazolidinium salt, and an isooxazolidinium salt; and salts of aliphatic compound such as a quaternary ammonium salt. An anion moiety in such viscosity-lowering agents is preferably NCS⁻, PF₆⁻, ClO₄⁻, BF₄⁻, (CF₃SO₂)₂N⁻, (C₂F₅SO₂)₂N⁻, CF₃SO₃⁻, CF₃COO⁻, Ph₄B⁻, etc. A more preferred anion is BF₄⁻ or (CF₃SO₂)₂N⁻. Specific examples of the viscosity-lowering agent include 1-propylpyridinium tetrafluoroborate, 1-propylpyridinium bis(trifluoromethyl sulfonyl)imide, 1-butylpyridinium hexafluorophosphate, 1-hexylpyridinium perchlorate, 1-methylpyridinium trifurate, 1-propylpyridinium trifluoromethane sulfonate, 1-methyl-3-propylimidazolium tetrafluoroborate, 1-methyl-3-propylimidazolium bis(trifluoromethyl sulfonyl)imide, 1-methyl-3-butylimidazolium hexafluorophosphate, 1-ethyl-3-methylimidazolium perchlorate, 1-methyl-3- propylimidazolium trifurate, 1-methyl-3-propylimidazolium trfluoromethasulfonate, tetrabutylammonium tetrafluoroborate, tetrabutyl ammonium bis(trifluoromethyl sulfonyl)imide, and methyltetrabutyl ammonium bis(trifluoromethyl sulfonyl)imide. These viscosity-lowering agents can be dissolved in molten salt of iodide at room temperature or by heating.

### (2) Semiconductor Electrode

A dye and carboxylic compound are carried on the surface of a semiconductor electrode of the embodiment of the invention. As the semiconductor electrode, it is preferred to use an n-type semiconductor electrode in order to obtain a high photoelectric characteristics.

A semiconductor electrode is formed, preferably, from a transparent semiconductor small in absorption in a visible light region. As such a semiconductor, a metal oxide semiconductor is preferred. Specific examples are oxides of transition metal such as titanium, zirconium, hafnium, strontium, zinc, indium, yttrium, lanthanum, vanadium, niobium, tantalum, chromium, molybdenum, and tungsten; perovskite such as SrTiO₃, CaTiO₃, BaTiO₃, MgTiO₃, and SrNb₂O₆; or their composite oxides or mixture of oxides; and GaN.

The dye to be adsorbed on the surface of this semiconductor electrode is, for example, a ruthenium-tris type transition metal complex, a ruthenium-bis type transition metal complex, an osmium-tris type transition metal complex, an osmium-bis type transition metal complex, a ruthenium-cis-diaqua-dipyrildyl complex, phthalocyanine, porphilline, etc. To adhere the dye to the semiconductor, a dye solution is brought into contact with the semiconductor. The dye can be adhered by immersing the semiconductor in the dye solution, or applying the dye solution to the semiconductor. The dye solution can be prepared by dissolving in a hydrophobic solvent, or a nonprotonic solvent, or a hydrophobic and nonprotonic solvent, and examples of the solvent include water and alcohols such as methanol and ethanol; ketones such as methyl ethyl ketone, acetone, and acetylacetone; and hydrocarbons such as hexane and cyclohexane. Preferably, the solvent should be refined by a conventional method. Prior to the use of the solvent, distilling or drying, or both is/are carried out as required, so that a solvent of a higher purity may be obtained.

Specific examples of the carboxylic compound include acetic acid, propionic acid, butyric acid, benzoic acid, o-bromobenzoic acid, m-bromobenzoic acid, p-bromobenzoic acid, 3-bromopropionic acid, α-bromo-p-toluic acid, 4-(bromomethyl)benzoic acid, o-chlorobenzoic acid, m-chlorobenzoic acid, p-chlorobenzoic acid, o-iodobenzoic acid, m-iodobenzoic acid, p-iodobenzoic acid, 4-bromoisophthalic acid, 2-(trimethylsilyl)acetic acid, and 2-thiophene carboxylic acid, but the use is not limited to these examples. One type or two or more types of carboxylic acids may be used. In particular, acetic acid, propionic acid and butyric acid are preferred because the molecular weight thereof is small and they are easily adsorbed on the surface of titanium oxide. A carboxylic compound formed of at least one type selected from the group consisting of acetic acid, propionic acid and butyric acid can densely cover a dye-free region on the semiconductor layer surface, and therefore, the energy conversion efficiency of the solar cell can be further improved.

The process of carrying carboxylic compound comes after the process of carrying a dye. A carboxylic compound layer is formed by carrying the carboxylic compound on a portion of the surface of the semiconductor layer where no dye is formed. Since the carboxylic compound has high adsorbability on the surface of the semiconductor, the semiconductor layer surface where no dye is formed can be covered. Moreover, since the carboxylic compound is capable of blocking transfer of electrons or holes, transfer of charge from the semiconductor layer surface into the electrolyte composition can be blocked. Therefore, the semiconductor electrode excellent in the optical characteristics such as open-circuit voltage and photoelectric conversion efficiency can be obtained.

To carry the carboxylic compound on the surface of the semiconductor layer, preferably, a solution containing the carboxylic compound is brought into contact with the semiconductor layer having the dye carried on the surface.

As the method for contact with the semiconductor layer, there are preferably, for example, a method in which the carboxylic compound is dissolved in a predetermined solvent to prepare a solution containing the carboxylic compound, and the semiconductor layer is immersed in the solution containing the carboxylic compound; a method in which the solution containing the carboxylic compound is sprayed; a method in which the solution containing carboxylic compound is applied by casting; and the like. Among these contact methods, from the viewpoint of efficiency of operation, high density of carboxylic compound layers, and ease of use, the method of immersing in the solution containing carboxylic compound is particularly preferred. Examples of the predetermined solvent include an organic solvent and water. The solvents may be used either alone or in combination of two or more types. Examples of the organic solvent include, for example, a hydrocarbon solvent, an ester solvent, an ether solvent, a halogen solvent, an alcohol solvent, and an amide solvent. When contacting, ultrasonic waves may be applied.

A preferred embodiment of the dye-sensitized solar cell using such electrolyte composition and semiconductor electrode will be explained below.

This preferred embodiment comprises a substrate having a light receiving surface, a transparent conductive layer formed on one side of the substrate, a semiconductor electrode formed on the transparent conductive layer and having a dye and carboxylic compound adsorbed on the surface thereof, a counter electrode including a conductive layer, and an electrolyte composition interposed between the conductive layer and the semiconductor electrode, and this has a structure of incidence of sunlight from the substrate. The counter electrode has a counter substrate opposite to the semiconductor electrode and a conductive layer formed on the surface of the counter substrate opposite to the semiconductor electrode.

Alternatively, it may be designed to allow the sunlight to enter from the counter electrode side by using transparent materials small in absorption in the visible light region as the counter substrate.

The transparent conductive layer, counter electrode, and conductive layer will be explained below.

### (A) Transparent Conductive Layer

The transparent conductive layer is preferred to be small in absorption in the visible light region and sufficient in conductivity. The transparent conductive layer is made of, preferably, a tin oxide film doped with fluorine or indium etc., or a zinc oxide film doped with fluorine or indium, etc. From the viewpoint of preventing elevation of resistance by improving the conductivity, it is preferred to use a metal matrix wiring of low resistance together with the transparent conductive layer.

### (B) Counter Substrate

The counter substrate is preferred to be small in absorption in the visible light region and sufficient in conductivity. The counter substrate is made of, preferably, a tin oxide film, a zinc oxide film or the like.

### (C) Conductive Layer

The conductive layer may be made of a metal such as platinum, gold or silver. By forming the conductive layer in a thin film, a transparent conductive layer of small absorption in the visible light region can be obtained.

The dye-sensitized solar cell of the embodiment of the invention may be manufactured, for example, in the following method.

First, a substrate having a light receiving surface is prepared, and a transparent conductive layer and a semiconductor electrode are formed sequentially on one side of the substrate. A dye and carboxylic compound are sequentially adsorbed on the surface of the semiconductor electrode. On the other hand, a counter electrode having a conductive layer provided on the surface of the counter substrate is prepared, the conductive electrode and the above semiconductor electrode are arranged oppositely apart from each other, and a cell unit is obtained.

In succession, an electrolyte composition precursor is injected into the gap between the semiconductor electrode and the conductive layer. To obtain a gel electrolyte layer, the electrolyte composition precursor is gelled. By sealing the cell unit consequently, the dye-sensitized solar cell of the embodiment of the invention is obtained.

When obtaining a gel electrolyte layer, it is preferred to heat the cell unit upon gelling the electrolyte composition precursor. The heating temperature is preferably in a range of 50 to 200° C. The reason is as follows. If the heating temperature is less than 50° C., the degree of polymerization of the gel is lowered, and it may be hard to form a gel. If heat treatment is carried out at high temperature exceeding 200° C., by contrast, the dye is likely to be decomposed. More preferably, the heating temperature is 70 to 150° C.

Specific examples will be further described below with referring to the accompanying drawings.

### EXAMPLE 1

First, as a material for an n-type semiconductor electrode, a commercial paste product (made by Solaronix in Switzerland) containing high purity titanium oxide (anatase) powder with average primary particle size of about 10 to 20 nm was prepared.

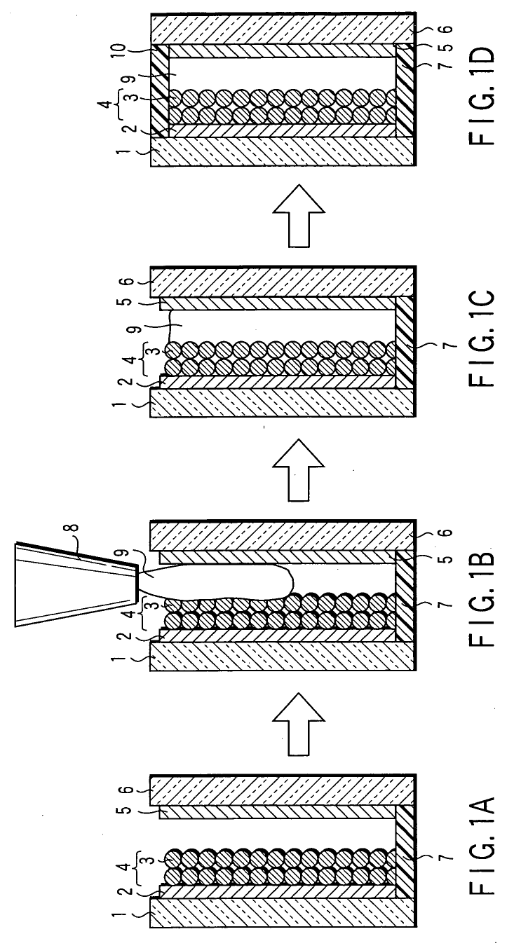

As shown in FIG. 1A, a fluorine-doped SnO₂ transparent electrode (6 Ω/□) 2 was formed on a glass substrate 1, and the paste was printed thereon by a screen printing method, and heated at temperature of 450° C. As a result, an n-type semiconductor electrode which contains titanium oxide (anatase) particles and has a thickness of 2 μm was formed.

By repeating such screen printing and heat treatment several times, finally, an n-type semiconductor electrode 4 made of titanium oxide particles 3 of anatase phase was formed in a thickness of 8 μm on the fluorine-doped tin oxide conductive layer 2 (transparent conductive layer 2). The roughness factor of this n-type semiconductor electrode 4 was 1500. The roughness factor was determined from the nitrogen adsorption amount for the projection area of the substrate.

On the other hand, cis-bis(thiocyanato)-N,N-bis (2,2′-dipyridyl-4,4′-dicarboxylic acid)-ruthenium (II) dihydrate) was dissolved in dry ethanol, and a dry ethanol solution of 3×10⁻⁴M was prepared. The manufactured n-type semiconductor electrode 4 was immersed in this solution for 12 hours at room temperature, and the dye adsorbing on an area other than the titanium oxide surface was washed away by alcohol, and dried. As a result, ruthenium complex was carried as a dye on the surface of the n-type semiconductor electrode 4.

After the n-type semiconductor electrode was immersed for 30 minutes in a solution in which acetic acid was dissolved in a dry acetonitrile to a concentration of 5×10⁻² mol/L, it was washed in acetonitrile (cleaning liquid), and dried in nitrogen atmosphere. Thus, the carboxylic compound was carried, and an n-type semiconductor electrode was fabricated.

A glass substrate having a fluorine-doped tin oxide electrode 5 (conductive layer 5) formed on the surface thereof was prepared as a counter substrate 6, a platinum layer was formed on the conductive layer 5 of this counter substrate 6, and a counter electrode was obtained. This counter electrode was opposite to the n-type semiconductor electrode with a spacer interposed therebetween and having a diameter of 15 μm. Further, leaving an injection port of the electrolyte, the periphery was filled and fixed with an epoxy resin 7.

By this operation, a photoelectric conversion element unit as shown in FIG. 1A was obtained.

The electrolyte was prepared as follows. 0.5 M of tetrapropyl ammonium iodide, 0.02 M of potassium iodide, and 0.09 M of iodine were dissolved in 1-methyl-3-propyl imidazolium iodide to prepare an electrolyte. 0.2 g of polyvinyl pyridine and 0.1 g of MgI₂ were added in 10 g of this electrolyte, and a gel electrolyte composition precursor was obtained.

Next, as shown in FIG. 1B, a gel electrolyte composition precursor 9 was injected into the opening of the photoelectric conversion unit from an injection port 8. The electrolyte composition precursor 9 was, as shown in FIG. 1C, injected also into the gap between the n-type semiconductor electrode 4 and the tin oxide electrode S (conductive layer 5) while permeating into the n-type semiconductor electrode 4.

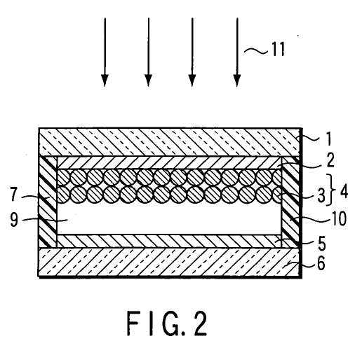

Consequently, as shown in FIG. 1D, the opening of the photoelectric conversion unit was sealed with an epoxy resin 10 and heated on a hot plate for 30 minutes at 60° C., and a photoelectric conversion element, that is, a dye-sensitized solar cell was manufactured. A sectional view of the obtained solar cell is shown in FIG. 2.

As shown in FIG. 2, the transparent conductive layer 2 and transparent n-type semiconductor electrode 4 are sequentially formed on the glass substrate 1. This n-type semiconductor electrode 4 is formed of fine particles 3, and the surface area is large. A monomolecular dye is adsorbed on the surface of the n-type semiconductor electrode 4, and its surface may be formed in a fractal shape having self-similarity like a resinous structure. On the surface of the n-type semiconductor electrode 4, in an area where no dye is formed, the carboxylic compound is absorbed, and the n-type semiconductor electrode 4 is covered with the dye and carboxylic compound. The counter electrode includes a glass substrate 6 as a counter substrate, and a conductive layer 5 formed on the surface of the glass substrate 6. The conductive layer 5 is opposite to the n-type semiconductor electrode 4 with the electrolyte composition interposed therebetween.

The electrolyte composition 9 is held in pores in the transparent n-type semiconductor electrode 4, and is interposed between the n-type semiconductor electrode 4 and the conductive film 5. In the embodiment of the invention, since a molten salt is contained in the electrolyte composition layer, the durability is high, and since carboxylic acid is formed in an area free from dye on the n-type semiconductor electrode 4, transfer of charge from the n-type semiconductor electrode 4 into the electrolyte composition can be blocked. In this dye-sensitized solar cell, when light 11 enters from the side of the glass substrate 1, first, the dye adsorbed on the surface of the n-type semiconductor electrode 4 absorbs the incident light 11 and is excited. The excited dye transfers electrons to the n-type semiconductor electrode 4, and also transfers the holes to the electrolyte composition, so that photoelectric conversion is executed. The energy conversion efficiency of this solar cell was 5.8%.

### EXAMPLE 2

A dye-sensitized solar cell was fabricated in the same composition as in Example 1, except that benzoic acid was used instead of acetic acid. The energy conversion efficiency of this solar cell was 5.6%.

### EXAMPLE 3

A dye-sensitized solar cell was fabricated in the same composition as in Example 1, except that 0.2 g of 1,2,4,5-benzene tetramethyl tetra(1-imidazole) was used instead of polyvinylpyridine. The energy conversion efficiency of this solar cell was 6.0%.

### EXAMPLE 4

A dye-sensitized solar cell was fabricated in the same composition as in Example 1, except that 0.2 g of 1,2,4,5-tetraxis(bromomethyl)benzene was used instead of MgI₂. The energy conversion efficiency of this solar cell was 6.2%.

### EXAMPLE 5

A dye-sensitized solar cell was fabricated in the same composition as in Example 1, except that 0.23 g of 1,6-dibromohexane was used instead of MgI₂. The energy conversion efficiency of this solar cell was 6.0%.

### EXAMPLE 6

A dye-sensitized solar cell was fabricated in the same composition as in Example 1, except that 0.23 g of 1,6-dibromohexane was used instead of MgI₂, and that benzoic acid was used instead of acetic acid. The energy conversion efficiency of this solar cell was 5.9%.

### EXAMPLE 7

An electrolyte was prepared by dissolving 0.2 M of iodine in 1-methyl-3-propyl imidazolium iodide. 0.2 g of polyvinyl pyridine and 0.2 g of 1,2,4,5-tetraxis(bromomethyl)benzene were added to 10 g of this electrolyte, and an electrolyte composition precursor was obtained. A dye-sensitized solar cell similar to that in Example 1 except for the electrolyte composition precursor was fabricated. The energy conversion efficiency of this solar cell was 6.0%.

### EXAMPLE 8

An electrolyte was prepared by adding iodine by 0.2 M in a molten salt obtained by mixing 1-methyl-3-propyl imidazolium iodide and 1-methyl-6-hexyl imidazolium iodide by 1 by 1 by weight. 0.2 g of polyvinyl pyridine and 0.2 g of 1,2,4,5-tetraxis(bromomethyl)benzene were added to 10 g of this electrolyte, and an electrolyte composition precursor was obtained. A dye-sensitized solar cell similar to that in Example 1 except for the electrolyte composition precursor was fabricated. The energy conversion efficiency of this solar cell was 5.8%.

### EXAMPLE 9

A dye-sensitized solar cell was fabricated in the same composition as in Example 8, except that propionic acid was used in stead of acetic acid. The energy conversion efficiency of this solar cell was 5.7%.

### EXAMPLE 10

A dye-sensitized solar cell was fabricated in the same composition as in Example 1, except that the electrolyte composition of the same composition as in Example 7 was used without adding a gelling agent. The energy conversion efficiency of this solar cell was 5.9%.

### EXAMPLE 11

A dye-sensitized solar cell was fabricated in the same composition as in Example 1, except that the electrolyte composition of the same composition as in Example 8 was used without adding a gelling agent. The energy conversion efficiency of this solar cell was 5.8%.

### COMPARATIVE EXAMPLE 1

A solar cell was fabricated in the same manner as in Example 1, except that the acetic acid treatment was skipped. The energy conversion efficiency of this solar cell was 4.0%.

### COMPARATIVE EXAMPLE 2

A solar cell was fabricated in the same manner as in Example 6, except that the benzoic acid treatment was skipped. The energy conversion efficiency of this solar cell was 3.5%.

### COMPARATIVE EXAMPLE 3

A solar cell was fabricated in the same manner as in Example 1, except that polyacrylonitrile was used instead of the gelling agent formed of polyvinyl pyridine and MgI₂, and that the acetic acid treatment was skipped. The energy conversion efficiency of this solar cell was 2.6%.

### COMPARATIVE EXAMPLE 4

A dye-sensitized solar cell was fabricated in the same manner as in Example 1, except that the liquid electrolyte composition was prepared by dissolving 0.5 mol/L of lithium iodide and 0.05 mol/L of iodine in propionitrile as a solvent. The energy conversion efficiency of this solar cell was 8.0%.

### COMPARATIVE EXAMPLE 5

A dye-sensitized solar cell was fabricated in the same manner as in Comparative example 4, except that the acetic acid treatment was skipped. The energy conversion efficiency of this solar cell was 7.4%.

### COMPARATIVE EXAMPLE 6

A dye-sensitized solar cell was fabricated in the same composition as in Example 1, except that methyl trimethoxy silane was used instead of acetic acid. The energy conversion efficiency of this solar cell was 4.4%.

### COMPARATIVE EXAMPLE 7

A dye-sensitized solar cell was fabricated in the same composition as in Example 11, except that the acetic acid treatment was skipped. The energy conversion efficiency of this solar cell was 3.8%.

In the solar cells of Examples 1 to 11 and Comparative examples 1 to 7, the energy conversion efficiency was determined by irradiating with artificial sunlight at intensity of 100 mW/cm². Next, after one-month storage of the solar cells of Examples 1 to 11 and Comparative examples 1 to 7 at 80° C., the energy conversion efficiency was determined by irradiating with artificial sunlight at intensity of 100 mW/cm², and compared with the energy conversion efficiency before storage, so that the lowering rate was determined. Results are shown in Table 1.

TABLE 1

| | Energy | |
|---|---|---|
| | conversion | Durability |
| | efficiency (%) | (%) |
| Example 1 | 5.8 | 4 |
| Example 2 | 5.6 | 5 |
| Example 3 | 6.0 | 4 |
| Example 4 | 6.2 | 4 |
| Example 5 | 6.0 | 4 |
| Example 6 | 5.9 | 4 |
| Example 7 | 6.0 | 4 |
| Example 8 | 5.8 | 5 |
| Example 9 | 5.7 | 4 |
| Example 10 | 5.9 | 4 |
| Example 11 | 5.8 | 4 |
| Comparative | 4.0 | 4 |
| example 1 | | |
| Comparative | 3.5 | 5 |
| example 2 | | |
| Comparative | 2.6 | 35 |
| example 3 | | |
| Comparative | 8.0 | 80 |
| example 4 | | |
| Comparative | 7.4 | 80 |
| example 5 | | |
| Comparative | 4.4 | 6 |
| example 6 | | |
| Comparative | 3.8 | 4 |
| example 7 | | |

The solar cells of Examples 1 to 11 were, as compared with the solar cells of Comparative examples 1 to 7, higher in the energy conversion efficiency, and smaller in the lowering rate of energy conversion efficiency by temperature rise, and are hence known to be excellent both in photoelectric conversion characteristic and in durability.

In comparison among examples, as compared with Example 2 using benzoic acid as carboxylic compound, Example 1 using acetic acid is higher in energy conversion efficiency. This is owing to the adsorbability on the semiconductor electrode when the surface of the semiconductor electrode is coated with the carboxylic compound, that is, the acetic acid has the largest power, which is followed sequentially by propionic acid and benzoic acid.

Among Examples 1, 4 and 5, as the gelling agent material, the halogen-containing compound is higher in energy conversion efficiency than the metal compound. This is because the halogen-containing compound is low in gelling speed so as to change into gel slowly, so that the electrolyte composition permeates deeply into the semiconductor electrode, and the ions transfer the carrier efficiently.

In the gelling agent containing polyvinyl pyridine and 1,2,4,5-tetraxis(bromomethyl)benzene, as in Examples 4 and 7, gelling was successful by a small amount.

Among comparative examples, the energy conversion efficiency is very low in Comparative examples 1, 2 and 7 in which treatment by the carboxylic compound was skipped.

In Comparative example 3, since treatment by the carboxylic compound was skipped, the energy conversion efficiency is low, and since a physical-gelling agent is used as a gelling agent, it is dissolved at high temperature, so that the characteristic deteriorates and the durability is lowered.

In Comparative examples 4 and 5, since the solvent and solute dissolved therein is used as the liquid electrolyte composition, the energy conversion efficiency is high, but the durability is extremely lowered. In comparison between Comparative examples 4 and 5, whether treated by the carboxylic compound or not, the energy conversion efficiency is improved only about 10%. On the other hand, when the examples in which the semiconductor electrode is applied to the carboxylic compound treatment are compared with Comparative examples 1 and 2 in which the semiconductor electrode is not applied to the carboxylic compound treatment, the energy conversion efficiency is improved by about 50%. Therefore, in the embodiment of the invention, while keeping a high durability, the energy conversion efficiency is notably improved.

As can be seen from Comparative example 6, when a molten salt is used as the electrolyte and the electrode is treated by a compound other than the carboxylic compound, the energy conversion efficiency is not improved so much.

### EXAMPLE 12

0.3 M of iodine was dissolved in 1-methyl-3-propyl imidazolium iodide, and water was added to the obtained mixture, thereby obtaining an electrolyte. The content of water in the electrolyte was 5 wt. %. 0.2 g of polyvinyl pyridine and 0.2 g of 1,2,4,5-tetraxis(bromomethyl)benzene were added to 10 g of this electrolyte, and an electrolyte composition precursor was obtained as a gel electrode precursor. A dye-sensitized solar cell similar in composition to that in Example 1 was fabricated, except that such an electrolyte composition precursor was used.

### EXAMPLE 13

A dye-sensitized solar cell similar in composition to that in Example 12 was fabricated, except that propionic acid was used instead of acetic acid.

### EXAMPLE 14

A dye-sensitized solar cell similar in composition to that in Example 12 was fabricated, except that butyric acid was used instead of acetic acid.

### EXAMPLE 15

A dye-sensitized solar cell similar in composition to that in Example 12 was fabricated, except that polyvinyl pyridine and 1,2,4,5-tetraxis(bromomethyl)benzene as a gelling agent were not added to the electrolyte.

### EXAMPLE 16

A dye-sensitized solar cell similar in composition to that in Example 12 was fabricated, except that benzoic acid was used instead of acetic acid.

### EXAMPLE 17

A dye-sensitized solar cell similar in composition to that in Example 12 was fabricated, except that 3-bromopropionic acid was used instead of acetic acid.

In the obtained solar cells of Examples 12 to 17, the energy conversion efficiency and energy conversion efficiency lowering rate were measured in the same condition as explained in Example 1, and results are shown in Table 2.

TABLE 2

| | | | Energy | Dura- |
|---|---|---|---|---|
| | Type of | Type of | conversion | bility |
| | electrolyte | carboxylic acid | efficiency (%) | (%) |
| Example 12 | Gel | Acetic acid | 6.6 | 7 |
| | electrolyte | | | |
| Example 13 | Gel | Propionic acid | 6.4 | 7 |
| | electrolyte | | | |
| Example 14 | Gel | Butyric acid | 6.3 | 7 |
| | electrolyte | | | |
| Example 15 | Liquid | Acetic acid | 7 | 8 |
| | electrolyte | | | |
| Example 16 | Gel | Benzoic acid | 6.1 | 12 |
| | electrolyte | | | |
| Example 17 | Gel | 3-Bromopropionic | 6 | 12 |
| | electrolyte | acid | | |

As clear from Table 2, the solar cells of Examples 12 to 15 comprising the electrolyte composition containing water and at least one type of carboxylic acid selected from the group consisting of acetic acid, butyric acid and propionic acid were higher in the energy conversion efficiency and smaller in the lowering rate as compared with the solar cells of Examples 16 and 17.

In the solar cell of Example 16, the energy conversion efficiency and durability are inferior to Examples 12 to 15. Since acetic acid, butyric acid and propionic acid each have a thin and long molecular structure compared to benzoic acid, they are likely to get in the gap formed between dye molecules absorbed onto the surface of a semiconductor particle. On the other hand, in the solar cell of Example 17, the energy conversion efficiency and durability are inferior to Examples 12 to 15, which seems to result from the fact that 3-bromopropionic acid is used in Example 17, that is, it is bulky and is inferior in adsorption on the semiconductor particles as compared with acetic acid, butyric acid and propionic acid. Although not specifically mentioned herein, 2-trimethylsilyl acetic acid also has a bulky trimethylsilyl group, the molecular size is large, it is also found to be inferior in adsorption on the semiconductor particles as compared with acetic acid, butyric acid and propionic acid.

As described herein, the embodiment of the invention provides a dye-sensitized solar cell high in energy conversion efficiency and excellent in durability.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A dye-sensitized solar cell comprising:
a semiconductor electrode containing a dye and carboxylic compound, the dye and carboxylic compound being carried on a surface of the semiconductor electrode;
a counter electrode; and
an electrolyte composition provided between the semiconductor electrode and the counter electrode, and containing an electrolyte that contains iodine and molten salt of iodide.

2. The dye-sensitized solar cell according to claim 1, wherein the electrolyte composition further contains a gelling agent.

3. The dye-sensitized solar cell according to claim 2, wherein the gelling agent includes polyvinyl pyridine.

4. The dye-sensitized solar cell according to claim 1, wherein the electrolyte composition further contains inorganic salt of iodide.

5. The dye-sensitized solar cell according to claim 1, wherein the electrolyte composition further contains a viscosity-lowering agent containing at least one compound selected from the group consisting of salt of nitrogen-containing heterocyclic compound (excluding halide of nitrogen-containing heterocyclic compound) and salt of aliphatic compound.

6. The dye-sensitized solar cell according to claim 1, wherein the molten salt of iodide includes iodide of nitrogen-containing heterocyclic compound.

7. The dye-sensitized solar cell according to claim 1, wherein the molten salt of iodide includes 1-methyl-3-propyl imidazolium iodide.

8. The dye-sensitized solar cell according to claim 1, wherein the carboxylic compound includes at least one acid selected from the group consisting of acetic acid, propionic acid and butyric acid.

9. The dye-sensitized solar cell according to claim 1, wherein the electrolyte further contains water.

10. The dye-sensitized solar cell according to claim 9, the content of water in the electrolyte is in a range from 0.01 wt. % to 10 wt. %.

11. The dye-sensitized solar cell according to claim 1, wherein the semiconductor electrode contains titanium oxide particles.

12. The dye-sensitized solar cell according to claim 1, wherein the electrolyte composition is substantially in the form of a liquid or a gel.
